(19) United States
(12) Patent Application Publication
(10) Pub. No.: US 2025/0051965 A1
(43) Pub. Date: Feb. 13, 2025

(54) SHOWERHEAD FOR FAST DELIVERY OF INCOMPATABLE PRECURSORS

(71) Applicant: Applied Materials, Inc., Santa Clara, CA (US)

(72) Inventors: Gautam PISHARODY, Newark, CA (US); Parth SWAROOP, Bangalore (IN); Xiaoxiong YUAN, San Jose, CA (US); Paneendra Prakash BHAT, Santa Clara, CA (US); Qiwei LIANG, Fremont, CA (US); Dmitry LUBOMIRSKY, Cupertino, CA (US); Adib KHAN, Santa Clara, CA (US); Douglas A. BUCHBERGER, Jr., Livermore, CA (US)

(21) Appl. No.: 18/232,668

(22) Filed: Aug. 10, 2023

(51) Int. Cl. C30B 35/00; C30B 25/02

(52) U.S. Cl. CPC C30B 35/00; C30B 25/02

(57) ABSTRACT

Disclosed herein are a showerhead and a deposition chamber containing the showerhead. The showerhead includes a first delivery network for a first precursor that comprises a first manifold connected with a first distribution system comprising a plurality of first distribution channels concentrically disposed around an axis, and a second delivery network for a second precursor that comprises a second manifold connected with a second distributions system comprising a plurality of second distribution channels concentrically disposed around the axis. The first delivery network and the second delivery network are isolated from each other within the showerhead.

### BACKGROUND

### Field

The present disclosure relates to a showerhead and an epitaxy apparatus containing the showerhead, and more specifically relates to a showerhead capable of delivering incompatible gases and distributing the same uniformly.

### Description of the Related Art

An epitaxy chamber can be used for atomic layer deposition (ALD) on a substrate. During ALD, many layers are deposited in cycles to reach a desired thickness for a material. In each cycle, different gases, also known as precursors, are introduced into a chamber alternately. These precursors recombine once they reach the surface of a substrate disposed within the chamber to form a single layer. As these gases are typically incompatible, the chamber needs to be purged before each gas is introduced into the chamber.

Current ALD deposition has several drawbacks. First, the deposition time is very long not only because many cycles are needed to deposit a sufficient number of layers, but also because each cycle requires a long time to feed a gas into the chamber and purge the same from the chamber prior to introducing the next gas. Second, ALD typically results in an unevenly deposited film on the substrate surface.

Thus, a need exists for an epitaxy chamber to have a shortened deposition time and improved uniformity for an ALD process.

### SUMMARY

Disclosed herein are a showerhead and an epitaxial growth apparatus containing the showerhead. The showerhead includes a first delivery network for a first precursor that comprises a first manifold connected with a first distribution system comprising a plurality of first distribution channels concentrically disposed around an axis, and a second delivery network for a second precursor that comprises a second manifold connected with a second distributions system comprising a plurality of second distribution channels concentrically disposed around the axis. The first delivery network and the second delivery network are isolated from each other within the showerhead.

In another example, an epitaxial growth apparatus comprises a chamber and a showerhead as set forth in the present application.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 illustrates a schematic top view of a processing system, according to an embodiment of the present application.

FIG. 2 illustrates a schematic cross-sectional view of a processing chamber, according to an embodiment of the present application.

FIG. 3 illustrates a schematic cross-sectional view of a showerhead, according to an embodiment of the present application.

FIG. 4 illustrates a schematic perspective view of a showerhead, according to an embodiment of the present application.

FIG. 5 illustrates a schematic bottom view of the showerhead of FIG. 4 according to an embodiment.

FIG. 6 illustrates a schematic cross-sectional view of the showerhead of FIG. 4, according to an embodiment of the present application.

FIG. 7A illustrates a schematic perspective top view of an adapter of the showerhead of FIG. 4 according to an embodiment.

FIG. 7B illustrates a schematic perspective bottom view of an adapter of the showerhead of FIG. 4 according to an embodiment.

FIG. 8A illustrates a schematic perspective top view of a top plate of the showerhead of FIG. 4 according to an embodiment.

FIG. 8B illustrates a schematic perspective bottom view of a top plate of the showerhead of FIG. 4 according to an embodiment.

FIG. 9 illustrates a schematic cross-sectional view of connections between an inlet and a second primary channel according to an embodiment.

FIG. 10A illustrates a schematic perspective top view of a bottom plate of the showerhead of FIG. 4 according to an embodiment.

FIG. 10B illustrates a schematic cross-sectional view of a bottom plate of the showerhead of FIG. 4 according to an embodiment.

FIG. 10C illustrates a schematic bottom view of a bottom plate of the showerhead of FIG. 4 according to an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

Disclosed herein is a showerhead for an epitaxial growth apparatus. The showerhead is configured to quickly deliver and uniformly distribute precursors to a substrate surface. For each precursor, the showerhead includes a dedicated delivery network which is isolated from the delivery network of another precursor. In this way, incompatible precursors will not contact each other within the showerhead.

For a precursor, the delivery network includes primary channels, distribution channels, and dispensing outlets. The primary channels and the distribution channels are disposed horizontally but at different heights within the showerhead. The primary channels and the distribution channels are coupled via a plurality of conduits disposed along a thickness direction of the showerhead. The distribution channels are distributed around the body of the showerhead and configured to distribute the precursor to the dispensing outlets at the bottom surface of the showerhead. Each distribution channel is coupled with a plurality of dispensing outlets for a fast and uniform release of the precursor to a chamber. The distribution channels and dispensing outlets are configured to uniformly distribute a precursor to a substrate surface. For example, the distribution channels and the dispensing outlets are concentrically distributed from a center to a perimeter of the showerhead.

The showerhead, by the configuration of the delivery network, is capable of reducing the cycle time. In addition, the configuration of the dispensing outlets improves the uniformity of deposited ALD layers.

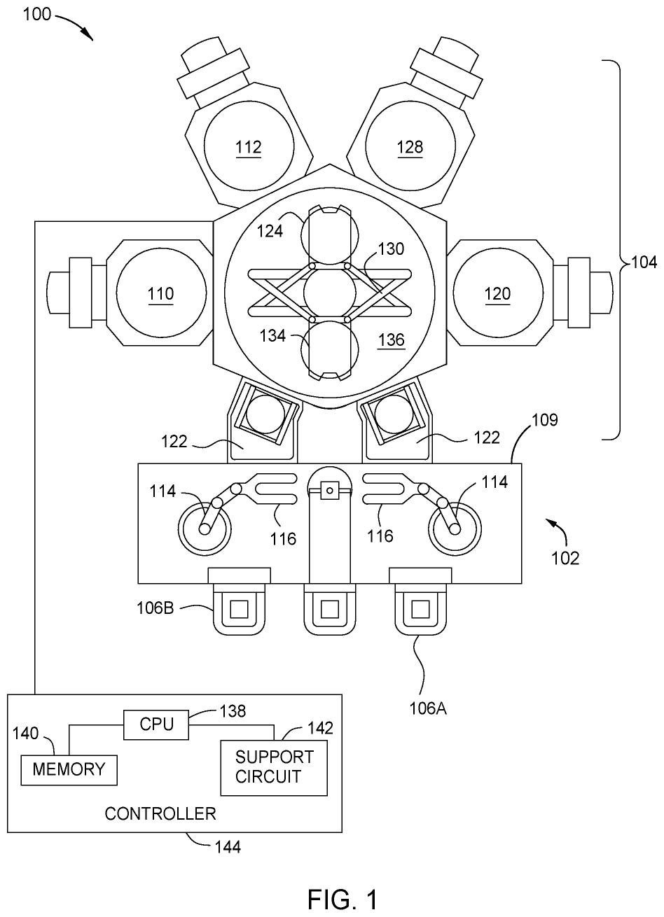

FIG. 1 illustrates a schematic top view of a processing system 100, according to one or more embodiments. The processing system 100 includes one or more load lock chambers 122 (two are shown in FIG. 1), a processing platform 104, a factory interface 102, and a controller 144. In one or more embodiments, the processing system 100 is a CENTURA® integrated processing system, commercially available from Applied Materials, Inc., located in Santa Clara, California. It is contemplated that other processing systems (including those from other manufacturers) may be adapted to benefit from the disclosure.

The processing platform 104 includes a plurality of processing chambers 110, 112, 120, 128, and the one or more load lock chambers 122 that are coupled to a transfer chamber 136. The transfer chamber 136 can be maintained under vacuum, or can be maintained at an ambient (e.g., atmospheric) pressure. Two load lock chambers 122 are shown in FIG. 1. The factory interface 102 is coupled to the transfer chamber 136 through the load lock chambers 122.

In one or more embodiments, the factory interface 102 includes at least one docking station 109 and at least one factory interface robot 114 to facilitate the transfer of substrates. The docking station 109 is configured to accept one or more front opening unified pods (FOUPs). Two FOUPS 106A, 106B are shown in the implementation of FIG. 1. The factory interface robot 114 having a blade 116 disposed on one end of the robot 114 is configured to transfer one or more substrates from the FOUPS 106A, 106B, into the load lock chambers 122. Substrates being transferred can be stored at least temporarily in the load lock chambers 122.

Each of the load lock chambers 122 has a first port interfacing with the factory interface 102 and a second port interfacing with the transfer chamber 136. The load lock chambers 122 are coupled to a pressure control system (not shown) which pumps down and vents the load lock chambers 122 to facilitate passing the substrates between the environment (e.g., vacuum environment or ambient environment, such as atmospheric environment) of the transfer chamber 136 and a substantially ambient (e.g., atmospheric) environment of the factory interface 102.

The transfer chamber 136 has a vacuum robot 130 disposed therein. The vacuum robot 130 has one or more blades 134 (two are shown in FIG. 1) capable of transferring the substrates 124 between the load lock chambers 122 and the processing chambers 110, 112, 120, and 128.

The controller 144 is coupled to the processing system 100 and is used to control processes and methods, such as the operations of the methods described herein (for example the operations of the method 1000 and/or the method 1050 described below). The controller 144 includes a central processing unit (CPU) 138, a memory 140 containing instructions, and support circuits 142 for the CPU. The controller 144 controls various items directly, or via other computers and/or controllers.

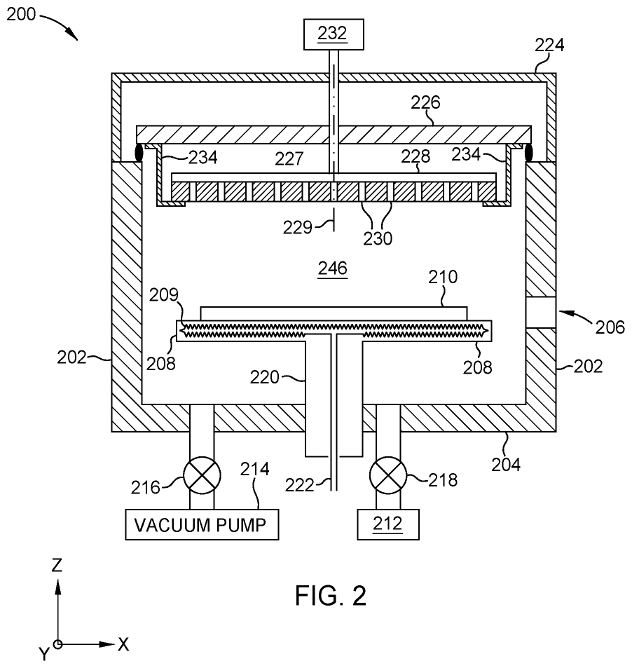

FIG. 2 illustrates a schematic cross-sectional view of a processing chamber 200 according to an embodiment. The processing chamber 200 may be any one of the processing chambers 110, 112, 128, and 120 as shown in FIG. 1. According to an embodiment, the processing chamber 200 is an epitaxy growth chamber. The processing chamber 200 in FIG. 2 includes walls 202, a bottom 204, and a chamber lid 224, which altogether enclose a processing region 246 and a substrate 210 disposed on a susceptor 220. The processing chamber 200 may also include a heating module (not shown) disposed around the bottom 204 and a plasma generator (not shown) disposed around the chamber lid 224. The wall 202 includes one or more ports 206 for transferring the substrate 210 into or out of the processing chamber 200. The susceptor 220 may include a heater that has heating elements 209 disposed in a heater body 208 and connected with an electrical source (not shown) via electrical leads 222.

The processing chamber 200 further includes a vacuum pump 214, an exhaust pump 212, and a gas source 232 containing a plurality of process gases. The plurality of process gases may be compatible or incompatible with each other. The vacuum pump 214 is coupled to the processing chamber 200 and configured to adjust the vacuum level via a valve 216. Vacuum pump 214 evacuates air or gas from the processing chamber 200 prior to substrate processing. The exhaust pump 212 is coupled to the processing chamber 200 and is configured to remove process gas out of the processing chamber 200 via a valve 218. The gas source 232 releases process gases into a gas showerhead 228 via conduits 227. The gas showerhead 228 may be attached to a support plate 226 by an adapter 234.

According to an embodiment, the gas showerhead 228 is configured to uniformly distribute the process gases from the gas source 232 to the processing region 246. The gas showerhead 228 includes one or more delivery networks configured to deliver and distribute process gases quickly and evenly into the process region 246 and/or the substrate 210. The one or more delivery networks are isolated from each other within the showerhead 228 to avoid any contact between incompatible process gases. According to an embodiment, for each incompatible process gas, the gas showerhead 228 includes a dedicated delivery network.

According to an embodiment, the delivery networks of the gas showerhead 228 include manifolds configured to deliver process gases from the one or more of the conduits 227 to distribution channels disposed within the gas showerhead 228. The distribution channels are arranged concentrically around a central axis 229 of the gas showerhead 228. These distribution channels are disposed horizontally and configured to spread the process gases quickly and evenly within the gas showerhead 228. The delivery networks of the gas showerhead 228 further include a plurality of dispensing outlets 230 concentrically arranged at the bottom surface of the gas showerhead 228. The dispensing outlets 230 may form clusters that are concentrically disposed around the central axis 229 of the gas showerhead 228. Every incompatible gas may have one or more dedicated conduits 227 and a dedicated delivery network with at least one outlet in a cluster. The dispensing outlets 230 are configured to distribute the process gas evenly within the processing region 246.

A cycle of deposition is generally performed by raising the temperature of the susceptor 220 and the substrate 210 to a predetermined degree. Then, the processing chamber 200 sequentially introduces one or more process gases, such as precursors, from the gas source 232 into the processing region 246. The process gases in processing region 246 may be energized (e.g., excited) into a plasma state. The excited gas reaches the surface of the substrate 210 and then reacts to form a layer of crystalline material on the surface of substrate 210. Then, the exhaust pump 212 is activated to remove residual process gas out of the chamber to conclude one cycle. Many cycles may be needed before the layer of a deposited crystalline material reaches a desired thickness.

The configuration, such as the primary channels and concentrically arranged distribution channels and dispensing outlets, of the showerhead 228 as disclosed in the present application reduces the time for the process gases to be introduced into the processing chamber and then evacuated. Considering many cycles are used to deposit materials to a desired thickness, this reduction of the cycle time can improve the throughput of an epitaxy process.

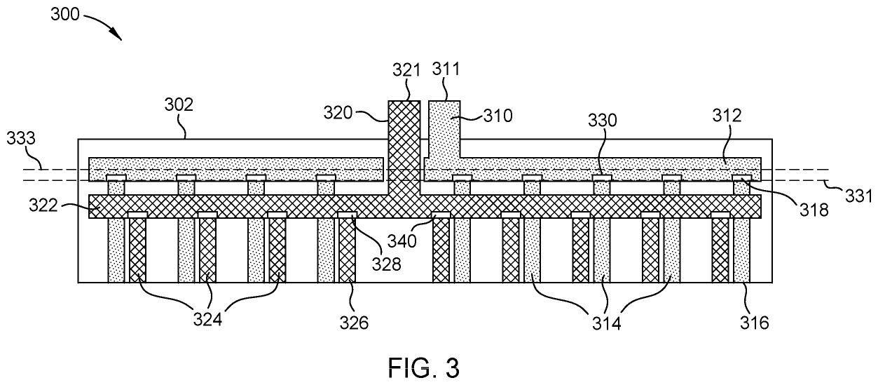

FIG. 3 illustrates a schematic cross-sectional view of a showerhead 300 according to an embodiment. The showerhead 300 includes a first delivery network 310 for a first precursor and a second delivery network 320 for a second precursor. According to an embodiment, the first precursor and the second precursor are incompatible with each other. The first delivery network 310 is configured to receive the first precursor via a first feeding main 311 (from, e.g., one of the dedicated conduits 227 and deliver the first precursor to a plurality of first dispensing outlets 316. The second delivery network 320 is configured to receive the second precursor via a second feeding main 321 (from another one of the dedicated conduits 227) and deliver the second precursor to a plurality of second dispensing outlets 326. As shown in FIG. 3, the first delivery network 310 and the second delivery network are both disposed within a body 302 of the gas showerhead 300, but are isolated from each other to avoid any contact between the first precursor and the second precursor. The showerhead 300 may be made of any suitable material that is configured to be compatible with the precursors. For example, the showerhead 300 may be made of aluminum alloys. The present application has contemplated that a greater number of delivery networks, such as three or four, may be disposed within the gas showerhead 300 in a manner similar with the first delivery network 310 and the second delivery network 320.

As shown in FIG. 3, the first delivery network 310 includes a first manifold and a first distribution system. The first manifold includes the first feeding main 311, a plurality of first primary channels 312, and a plurality of first feeding ports (not shown) disposed along the plurality of primary channels 312. The first manifold is configured to deliver the first precursor from the first feeding main 311 to the primary channels 312, and then to the first distribution system.

The first distribution system includes a plurality of first distribution channels 330, a plurality of first branch ports 318, a plurality of first passages 314, and the plurality of first dispensing outlets 316. The first distribution channels 330 receive the first precursor via the first feeding ports disposed along the primary channels 312. Then, the first precursor leaves the distribution channels 330 via the plurality of the branch ports 318 and enters the first passages 314. The first precursor gets released from the showerhead 300 via the plurality of dispensing outlets 316.

As shown in FIG. 3, the second delivery network 320 may include a second manifold and a second distribution system. The second manifold includes the second feeding main 321, a plurality of second primary channels 322, and a plurality of second feeding ports (not shown) disposed along the plurality of second primary channels 322. The second distribution system includes a plurality of second distribution channels 340, a plurality of second branch ports 328, a plurality of second passages 324, and the plurality of second dispensing outlets 326. The second delivery network 320 may be similarly configured as the first delivery network 310.

According to an embodiment, the plurality of first distribution channels 330 are concentrically disposed within the showerhead 300. The plurality of the first distribution channels is disposed substantially in a horizontal plane 331. The plurality of primary channels 312 may be disposed in a plane 333 that is parallel with the horizontal plane 331. According to an embodiment, the plurality of second distribution channels 340 are also concentrically disposed within the showerhead 300. The plurality of the first distribution channels and the second distribution channels may be alternately disposed within the showerhead 300. According to another embodiment, one or the first dispensing outlets 316 and one of the second dispensing outlets 326 form a pair of dispensing outlets. Pairs of the dispensing outlets are concentrically disposed along a bottom surface of the showerhead 300.

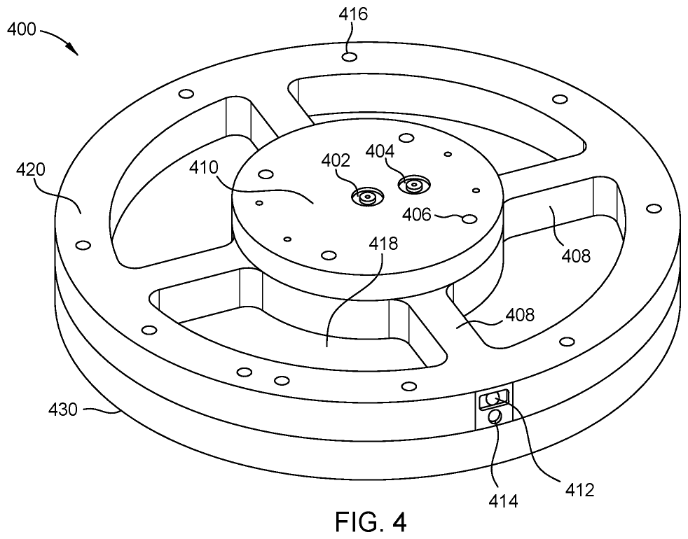

FIG. 4 illustrates a schematic perspective view of a showerhead 400, according to an embodiment of the present application. According to an embodiment, the showerhead 400 of FIG. 4 has a substantially circular shape and includes an adaptor 410, a top plate 420, and a bottom plate 430. The adaptor 410 is configured to couple the gas source 232 (FIG. 2) with feeding mains 321, 311 (FIG. 3) of the showerhead 400 and guide the precursors to inlet points of the top plate 420. The top plate 420 includes the primary channels 312, 322 (FIG. 3) and the feeding ports. The bottom plate 430 including the branch ports 318, 328 (FIG. 3), the passages 314, 324 (FIG. 3), and the dispensing outlets 316, 326 (FIG. 3). The top plate 420 and the bottom plate 430 are coupled together to form the distribution channels 330, 340 (FIG. 3). In an example, the top plate 420 includes one part of the distribution channels 330, 340 disposed at the bottom surface, while the bottom plate 430 includes the other part of the distribution channels 330, 340 disposed at the top surface.

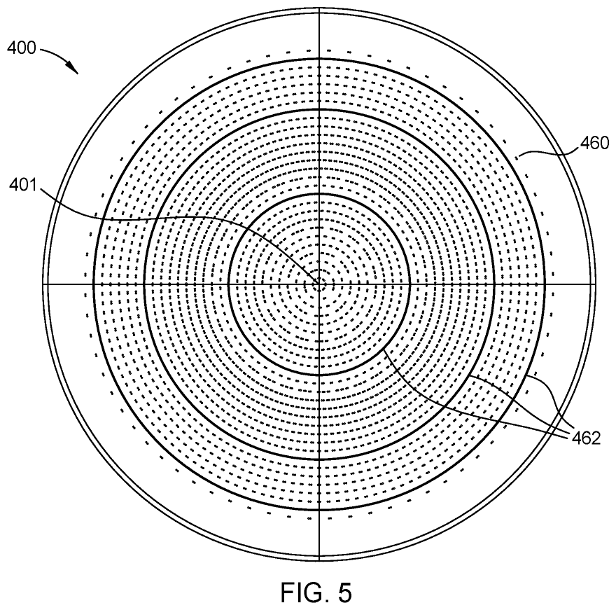

As shown in FIG. 4, the adaptor 410 includes a first feeding main 402 for the first precursor and a second feeding main 404 for the second precursor. The first feeding main 402 may be disposed along a central axis 401 (FIG. 5) of the showerhead 400. The adaptor 410 also includes a plurality of fasteners 406 that secure the adaptor 410 to the top plate 420 and form a gas-tight seal. The top plate 420 has a plurality of cavities 418 formed among a plurality of ribs 408. According to an embodiment, the ribs 408 contain primary channels. For example, a first primary channel 412 for the first precursor and a second primary channel 414 for the second precursor are disposed in each segments of ribs 408. The first primary channel 412 and the second primary channel 414 may be disposed on top of each other, side by side, or in other suitable arrangements. The plurality of ribs 408 are configured to evenly divide the coverage area of the showerhead 400 such that the primary channels 412 and 414 can cover the showerhead evenly. The bottom plate 430 and the top plate 420 are fastened by a plurality of fasteners 416 such that the distribution channels and gas-tight seals are formed in contact areas.

FIG. 5 illustrates a schematic bottom view of the showerhead 400 of FIG. 4, according to an embodiment. The dispensing outlets 326 and 316 (FIG. 3) are arranged in a plurality of circles 462 that share a common central axis 401. Each circle 462 includes a plurality of clusters 460 of dispensing outlets. Each cluster 460 may include at least one first dispensing outlet 316 (FIG. 3) for the first precursor and one second dispensing outlet 326 (FIG. 3) for the second precursor. The density of the clusters 460 along each circle 462 is configured to dispense the first precursor and the second precursor substantially evenly into the processing region 246 and the substrate 210 (FIG. 2). According to an embodiment, the concentric circles 462 are equally distanced from each other.

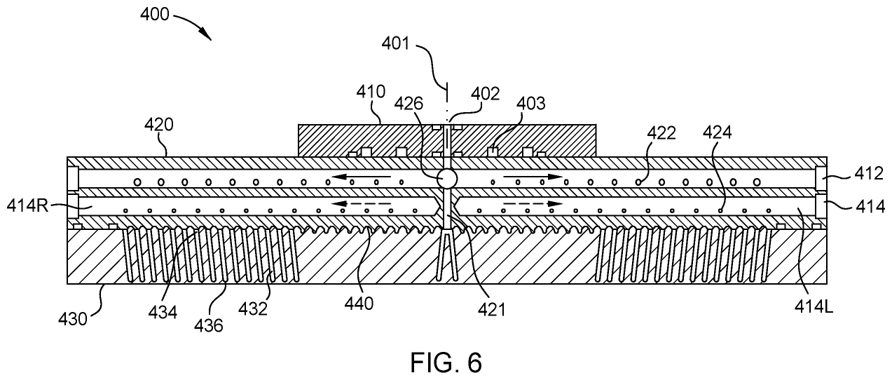

FIG. 6 illustrates a schematic cross-sectional view of the showerhead 400 along the N-N line of FIG. 5, according to an embodiment of the present application. The showerhead 400 includes the central axis 401. The adaptor 410 includes the first feeding main 402 disposed along the central axis 401. The first feeding main 402 is coupled with the first primary channels 412 for the first precursor via a joint 426 to deliver Gas A into the primary channels 412. A first passage 421 is disposed along the central axis 401 to couple the first feeding main 402 with the primary channels 412 and a channel at the bottom surface of the top plate 420. The first primary channels 412 are interconnected with each other via the joint 426 which delivers the first precursor from the first feeding main 402 to the first primary channels 412.

The adaptor 410 also includes the second feeding main 404 whose view is blocked by the first feeding main 402. The adaptor 410 further includes a plurality of adaptor passages 403 that distribute the second precursor within the adaptor 410. The adaptor passages 403 are coupled with the second primary channels 414 to deliver the second precursor from the second feeding main 404 to the second primary channels 414.

The top plate 420 includes first primary channels 412 and second primary channels 414 for Gas A and Gas B, respectively. The first primary channels 412 include a plurality of first feeding ports 422 disposed on a side wall from the central axis 401 toward the edges of the showerhead 400. The first feeding ports 422 connect the first primary channels 412 to a plurality of first distribution channels 440. According to an embodiment, the size of the first feeding ports 422 gradually increase from the central axis 401 to the edges to compensate for the pressure drop along the first primary channels. For example, the diameter of a feeding port adjacent to the edge may double the size of a feed port adjacent to the central axis 401.

The first feed ports 422 are connected with the plurality of the first distribution channels 440 via a first passages (not shown) disposed within the top plate 420. The first distribution channels 440 are dedicated for the first precursor. According to an embodiment, the bottom surface of the top plate 420 includes a first half of the first distribution channels 440, while a top surface of the bottom plate 430 includes the other half of the first distribution channels 440. When the bottom surface of the top plate 420 and the top surface of the second plate 430 are in contact, the first half and the second half of the first distribution channels 440 are coupled in a manner to form the first distribution channels 440.

Similarly with the first precursor, the second precursor has dedicated second primary channel 414, second feeding ports 424, and a plurality of second distribution channels 330 (FIG. 3). The plurality of second feeding ports 424 are disposed along a side wall of the second primary channel 412 with their sizes gradually increased from the central axis 401 to the edges.

According to an embodiment, the second primary channels 414R and 414L are separated from each other by a wall at the central axis 401 because the first feeding main 402 and its passages have occupied the area around the central axis 401. The second primary channels 414 are configured to interconnect with each other via the adapter passages 403 in the adaptor 410.

According to an embodiment, the distribution channels 440, 340 are arranged concentrically around the central axis 401. The distribution channels include a first set of distribution channels 440 for the first precursor and a second set of distribution channels 340 (FIG. 3) for the second precursor. The first set of distribution channels and the second set of distribution channels are isolated from each other to avoid contacts between the first precursor and the second precursor. According to an embodiment, the first set of distribution channels and the second set of distribution channels are alternately disposed within the showerhead 400.

The bottom plate 430 includes passages 432 that couple a plurality of branch ports 434 with the dispensing outlets 436. The branch ports 434 are disposed in the first distribution channels 440 and configured to allow a precursor to leave the first distribution channels 440 and enter the passages 432. According to an embodiment, the passages 432 are slanted, which form an angle relative to the central axis 401. In one example, the angle is configured to cause the passages 432 to direct the precursors slightly toward the central axis 401. The plurality of the dispensing outlets 436 are concentrically arranged on the bottom surface of the showerhead 400.

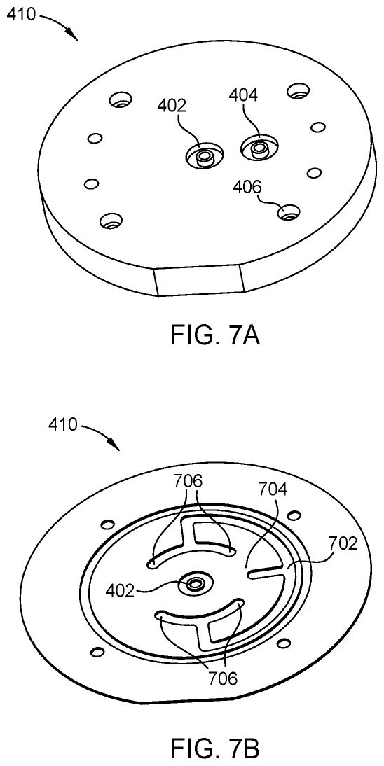

FIGS. 7A and 7B illustrate schematic perspective top and bottom views of the adaptor 410, respectively, according to an embodiment. The first feeding main 402 for the first precursor extends from a top surface to the bottom surface of the adaptor 410. The second feeding main 404 is connected with adaptor passages 702 formed at the bottom surface of the adaptor 410. The adaptor passages 702 are configured to guide the precursor from the second feeding main 404 to a plurality of inlets of the top plate 420 (FIG. 4) for coupling with the second primary channels 414 (FIG. 4). As shown in FIG. 7B, the passages 702 include a port 704 coupled with the second feeding main 404 and a plurality of arced channels. The arced channels connect the port 704 with a plurality of inlets 706 that couple with a second primary channel 414 of the top plate 420. The plurality of inlets 706 are symmetrically arranged around the first feeding main 402.

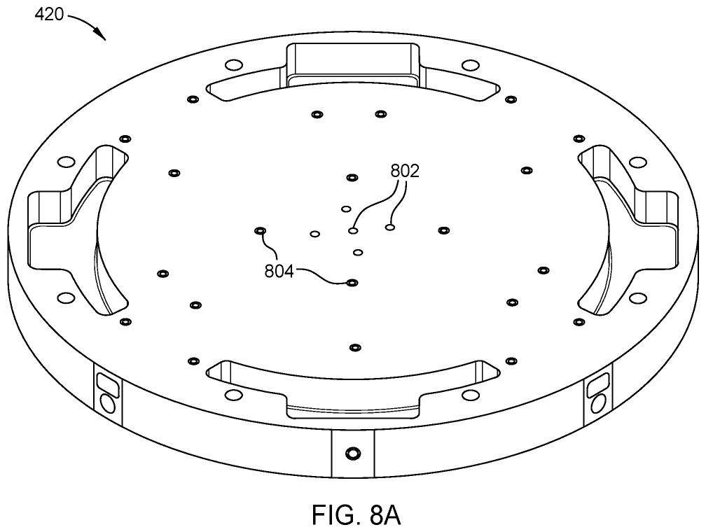

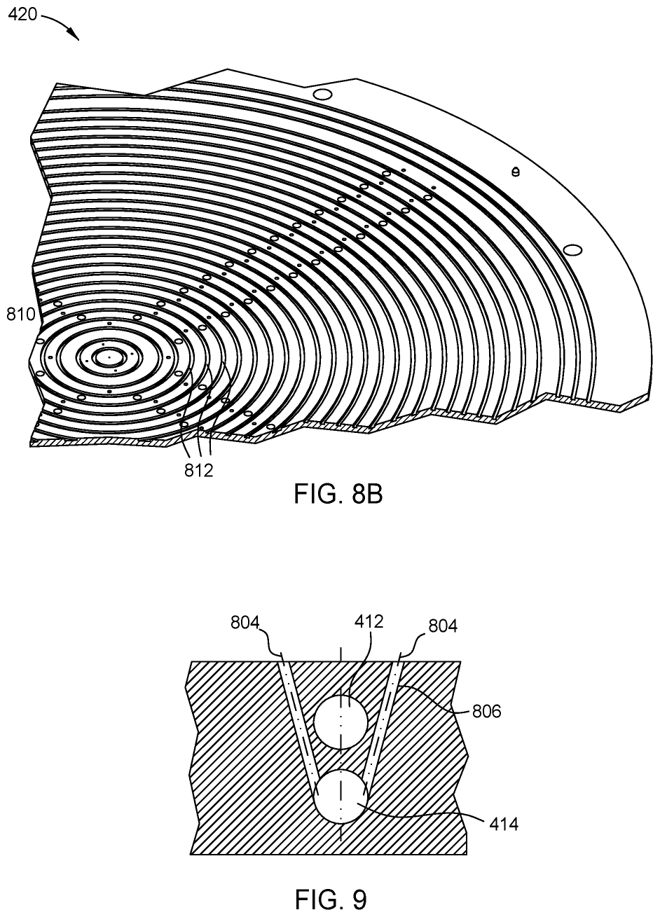

FIG. 8A illustrates the top view of a top plate 420, according to an embodiment. The top plate 420 includes a plurality of first inlets 802 for the first precursor and a plurality of second inlets 804 for the second precursor. The first inlets 802 connect the first feeding main 402 with the first primary channels 412 (FIG. 4). The second inlets 804 connect the second feeding main 404 via the arced channels and the feeding points 706 of the adaptor 410 (FIG. 7). The second inlets 804 are also connected with the second primary channels 414 (FIG. 4). FIG. 9 illustrates connections between the second inlets 804 and the second primary channels 414 according to an embodiment. As shown in FIG. 9, a first primary channel 412 is above the second primary channel 414. To connect the second inlets 804 with the second primary channel 414, a plurality of slanted passages 806 are drilled to bypass the first primary channel 412.

FIG. 8B illustrates a bottom view of the top plate 420 according to an embodiment. The bottom surface of the top plate 420 includes first halves of a plurality of first distribution channels 810 that are concentrically arranged. The halves of the distribution channels 810 include a plurality of ports 812 that receive the first precursor from the first primary channels 412. The plurality of the ports 812 are generally arranged to follow contours of the first primary channels 412.

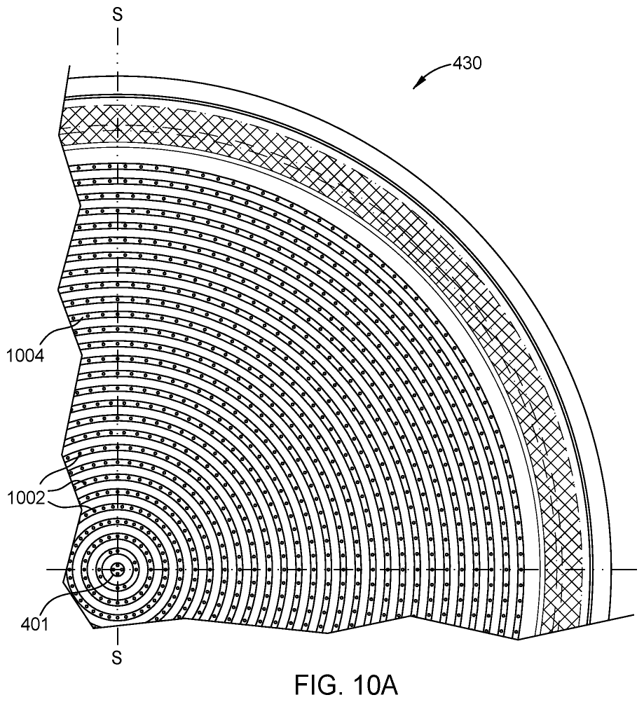

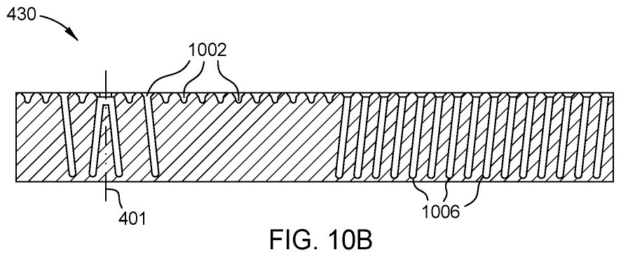

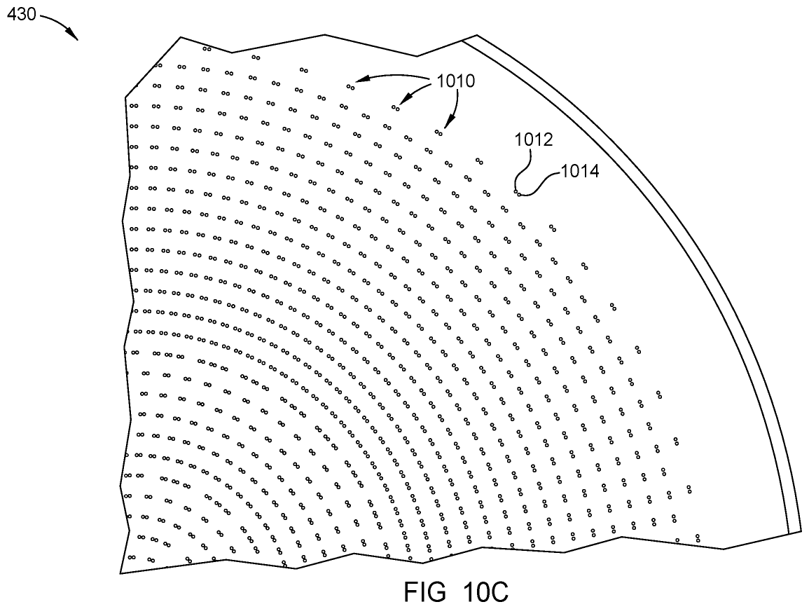

FIG. 10A illustrates a top view of the bottom plate 430, according to an embodiment. The top surface of the bottom plate 430 includes a plurality of second halves of the first distribution channels 1002 for the first precursor. These halves of the first distribution channels 1002 are concentrically arranged around the central axis 401. The second halves 1002 and the first halves 810 (FIG. 8B) are configured to couple with each other to form the plurality of the first distribution channels. For each first distribution channel 440 (FIG. 4), a plurality of first branch ports 1004 are provided to dispense the first precursor to the dispensing outlets.

FIG. 10B illustrates a schematic cross-sectional view along the S-S line of the bottom plate 430 in FIG. 10A, according to an embodiment. The bottom plate 430 includes a plurality of first passages 1006 that connects the first branch ports 1004 with the dispensing outlets 316, 326 (FIG. 3). According to an embodiment, the first passages 1006 may be slanted toward the central axis 401.

FIG. 10C illustrates a schematic bottom view of the bottom plate 430 according to an embodiment. The bottom surface includes a plurality of dispensing outlets 1012, 1014 that are concentrically arranged. The plurality of dispensing outlets 1012, 1014 may form a plurality of clusters 1010 which are also concentrically arranged. Each cluster 1010 may include a first dispensing outlet 1012 for the first precursor and a second dispensing outlet 1014 for the second precursor. In this way, the first and second precursor can be evenly dispensed from the bottom surface of the bottom plate 430.

It is contemplated that one or more aspects disclosed herein may be combined. Moreover, it is contemplated that one or more aspects disclosed herein may include some or all of the aforementioned benefits. While the foregoing is directed to embodiments of the present disclosure, other and further embodiments of the disclosure may be devised without departing from the basic scope thereof, and the scope thereof is determined by the claims that follow.

1. A showerhead within a deposition chamber, the showerhead comprising:
a first delivery network for a first precursor that comprises a first manifold connected with a first distribution system comprising a plurality of first distribution channels concentrically disposed around an axis; and
a second delivery network for a second precursor that comprises a second manifold connected with a second distribution system comprising a plurality of second distribution channels concentrically disposed around the axis,
wherein the first delivery network and the second delivery network are isolated from each other within the showerhead.

2. The showerhead according to claim 1, wherein the first manifold comprises a first feeding main connected with a plurality of first primary channels, the plurality of first primary channels are disposed in a first plane that is parallel with a second plane formed by the plurality of first distribution channels.

3. The showerhead according to claim 2, wherein the plurality of first primary channels comprise a plurality of first feeding ports connected with the plurality of first distribution channels, the sizes of the plurality of first feeding ports increase from the axis to an edge of the showerhead.

4. The showerhead according to claim 3, wherein the sizes of the plurality of first distribution channels increase from the axis to the edge of the showerhead.

5. The showerhead according to claim 3, wherein the plurality of first feeding ports are disposed along a side wall of the plurality of the first primary channels.

6. The showerhead according to claim 5, further comprising a plurality of slanted upper passages connecting the plurality of first feeding ports to the plurality of first distribution channels.

7. The showerhead according to claim 2, wherein the plurality of the first primary channels are interconnected via a joint disposed at a center of the showerhead.

8. The showerhead according to claim 2, further comprising the plurality of first primary channels are separated by a wall disposed at a center of the showerhead.

9. The showerhead according to claim 2, wherein the plurality of first distribution channels comprise a plurality of first branch ports connected with a plurality of first dispensing outlets disposed at a bottom surface of the showerhead.

10. The showerhead according to claim 9, wherein the plurality of first dispensing outlets are concentrically arranged at the bottom surface of the showerhead.

11. The showerhead according to claim 9, further comprising a plurality of slanted lower passages connecting the plurality of first branching ports with the plurality of first dispensing outlets.

12. The showerhead according to claim 1, wherein a plurality of the first distribution channels of the first delivery network and a plurality of the second distribution channels of the second delivery network are alternately arranged within the showerhead.

13. The showerhead according to claim 12, further comprising a plurality of clusters of dispensing outlets concentrically arranged at a bottom surface of the showerhead, wherein each cluster of the dispensing outlets comprises at least one first dispensing outlet of the first delivery network and at least one second dispensing outlet of the second delivery network.

14. The showerhead according to claim 1, further comprising a top plate coupled with a bottom plate.

15. The showerhead according to claim 14, wherein the first manifold is disposed within the top plate.

16. The showerhead according to claim 15, wherein the top plate comprises a first half of the plurality of first distribution channels, and the bottom plate comprises a second half of the plurality of first distribution channels.

17. The showerhead according to claim 16, further comprising an adaptor coupled with a top surface of the top plate and comprising a first inlet for the first precursor and a second inlet for the second precursor.

18. A deposition chamber comprising:
a chamber operable to receive a first precursor and a second precursor; and
a showerhead comprising:
a first delivery network for a first precursor that comprises a first manifold connected with a first distribution system comprising a plurality of first distribution channels concentrically disposed around an axis; and
a second delivery network for a second precursor that comprises a second manifold connected with a second distributions system comprising a plurality of second distribution channels concentrically disposed around the axis,
wherein the first delivery network and the second delivery network are isolated from each other within the showerhead.

19. The deposition chamber according to claim 18, wherein the first manifold comprises a first feeding main connected with a plurality of first primary channels, the plurality of the first primary channels are disposed on a first plane that is parallel with a second plane formed by the plurality of first distribution channels.

20. The deposition chamber according to claim 19, wherein the plurality of first distribution channels comprises a plurality of first branch ports connected with a plurality of first dispensing outlets disposed concentrically at a bottom surface of the showerhead.
